(19) United States
(12) Patent Application Publication
(10) Pub. No.: US 2011/0272367 A1
(43) Pub. Date: Nov. 10, 2011

(54) DEVICE FOR SUPPORTING SOLAR MODULES

(76) Inventor: Johann Kufner, Aholmnig (DE)

(21) Appl. No.: 13/097,932

(22) Filed: Apr. 29, 2011

(30) Foreign Application Priority Data
May 4, 2010 (DE) 20 2010 006 443.0

(51) Int. Cl. H01L 23/12

(52) U.S. Cl. 211/41.1

(57) ABSTRACT

A device for supporting solar modules, including several posts arranged in a row, wherein a head piece is attached to each post in its upper end region and at each head piece a transverse beam oriented more or less transversely to the row of posts is fixed, characterized in that the head piece is a profiled element, and that there is a strut between each transverse beam and the post, at the head piece of which the transverse beam is fixed.

### BACKGROUND OF THE INVENTION

The invention relates to a device for supporting solar modules, comprising several posts in a row, wherein a head piece is attached to each post in its upper end region, and at each head piece a transverse beam oriented more or less transversely to the row of posts is fixed.

Supports with transverse beams of this type are used when erecting solar plants and allow that the usually plate-shaped solar modules are mounted in a work plane which is inclined relative to the horizontal plane. Usually, the transverse beams are not directly attached to the posts, which are anchored in the ground, but they are attached via a head piece. In most solutions according to the prior art, said head piece is complexly designed, for example canted in various directions, which makes it expensive to manufacture and labor-intensive to mount.

DE 20 2005 008 159 U1, for example, describes a generic device for supporting solar modules, wherein two downward-pointing angles are attached to the lower side of each transverse beam, which angles are fixed or bolted to opposite sides of a post. Therefore, two separate, differently shaped head pieces are required.

DE 20 2009 016 353 U1 also discloses to attach two so-called transverse beam holders to each post. Said transverse beam holders are very complexly designed since the transverse beam is fixed to the first transverse beam holder by means of a first supporting joint and to the second transverse beam holder by means of a second supporting joint. The height distance of the two supporting joints in the longitudinal direction of the post can be adjusted variably so that the angle of inclination of the transverse beam can be adjusted. Also this solution is complex and, thus, cost-intensive, due to the required joints.

Finally, DE 20 2008 002 297 U1 discloses a support arrangement for a solar plant, wherein the transverse beams are designed such that they can be fixed to the respective posts alternatively in several support locations, which provide different inclinations of the support plane relative to the horizontal plane. To this end, the transverse beams are essentially U-shaped. The flanges or legs of the U are very long since corresponding fastening holes are arranged therein. Consequently, no head piece is required on the post, however, the transverse beams are designed accordingly complex and cannot be made from standard profiles.

Therefore, the object underlying the invention is to provide a device for supporting solar modules, which device provides an inexpensive and fast-to-mount possibility of attaching transverse beams to posts. A further object is to allow a variation in the angle of inclination of the transverse beams with simple means.

### SUMMARY OF THE INVENTION

In the following description, reference is made to one post, one head piece, one transverse beam and one support, respectively; however, in fact, one of the respective components is attributed to each of the at least two—preferably more—posts in a row.

Usually, the posts are positioned more or less vertically and anchored in the ground, in a foundation or on a rooftop. At the upper end of each post, a profiled element is attached as head piece, wherein profiled element means a component, the cross-section of which is essentially constant over its entire length. Most profiles are made from a sheet material by means of rolling in a continuous process and cut as is desired. The head piece according to the invention can have a length of 200-500 mm and a width of 50-120 mm, for example. Preferably, the head piece is formed as a single piece, and particularly preferably it is a metal profile, in particular a steel profile.

A strut is a girder-like strutting which is attached to the post at one end below the head piece and at the other end approximately midway between the center and one end of the transverse beam.

Preferably, the device has also several longitudinal beams, which are more or less parallel to the row of posts, and which are attached to the transverse beams. Together, the transverse beams and the longitudinal beams form the so-called support frame. The solar modules are preferably attached on the longitudinal beams. Typically, the solar modules are plate-shaped photovoltaic modules.

Usually, the transverse beam is fixed to the head piece approximately, however not exactly, at half its length so that the fastening point is near the center of gravity of the support frame carrying the solar modules.

Preferably, the longitudinal direction of the profiled element of the head piece is parallel to the longitudinal direction of the post. To put it differently, the profile of the head piece is constant in the longitudinal direction of the post, which is mostly more or less vertically oriented. Preferably, also the post is a profiled element oriented in the longitudinal direction. As a result, the head piece can easily rest or fit against the profiled element of the post.

According to a preferred embodiment, the strut can be attached to the post at least two vertically spaced locations, wherein the transverse beam in one of the locations has the angle of inclination desired for maximizing the solar irradiation, and in another location has a smaller angle of inclination relative to the horizontal plane, in particular is oriented more or less horizontally. For example, the strut is attached to the transverse beam and the post by usual fastening means such as bolts and nuts. Therefore, preferably, each of the at least two vertically spaced locations in the post is defined by a respective elongated hole. Said hole can be provided either directly in the post or in an angle piece attached to the post. A fastening element such as a bolt/screw or rivet can be guided through the elongated hole.

In this embodiment, the transverse beam can be mounted on the post by attaching the strut at the upper location, at first in a horizontal or only slightly inclined position. This position makes it easier to mount the longitudinal beams and the solar modules. After they have been mounted, the entire support frame can be inclined to the actual operating position, in which—depending on the latitude—maximal solar irradiation is expected, by releasing the strut and attaching it again in a lower location corresponding to this inclination.

The strut can be designed as a flat material blank or preferably as an L or U profiled element, at the ends of which, in the middle part or bridge of the profile, respective holes are arranged, at which the strut is attached, in particular bolted, to the post or the transverse beam, respectively.

The posts themselves are typically designed as steel girders, wherein said girders can be designed as U beams or double T beams. Preferably, the same head pieces can be employed both for U beams and for double T beams, wherein the latter may be IPE beams in particular. The use of standard IPE profile steel beams will reduce the costs of manufacture.

Preferably, the head piece is positively and/or frictionally attached to the post. Preferably, no adhesive bond such as welding or brazing/soldering is necessary since this is time-consuming and cost-intensive. Instead, preferably fastening elements such as bolts and nuts, rivets or the like are used. The same applies when attaching the transverse beam at the head piece.

Preferably, the head piece is designed as an L or U profiled element with one or two flanges or leg sections and a flat bridge (also referred to as middle part). Such profiled elements are more solid than a simple flat material blank. The posts can also be designed as profiled elements having one or more flanges and a bridge. Preferably, the middle part of the head piece rests against the bridge or middle part of the profiled beam of the post. Fastening is also done preferably from bridge to bridge. Preferably, the middle part of the head piece rests positively against the bridge of a post. Positively means here that the flanges of the post prevent the head piece from slipping sideways. In the vertical direction, the connection is preferably provided by means of connecting elements, which are guided through corresponding holes in the middle part of the head piece and in the bridge of the post.

In a preferred embodiment, the head piece is designed as a U profiled element having two leg sections and a flat middle part connecting said legs. With its middle part, the head piece rests against the post and the transverse beams and is attached to the post and the transverse beam by means of connecting elements, in particular bolt-nut-pairs, which grip through holes arranged in the middle part. Consequently, the head piece can be easily positioned and bolted to the post. In the next step, it is just as easy to position the transverse beam with a more or less vertically oriented wall at the also vertically oriented middle part of the head piece and to attach, in particular bolt it, thereto.

In its upper end region the head piece comprises at least two, preferably three or four, horizontally spaced holes, wherein the transverse beam is attached, in particular bolted, at one of the holes. The several horizontally spaced holes make it possible to easily balance deviations in the positioning of the posts if said posts are not exactly in a row due to the surface condition of the ground. In order to obtain a support frame, it is important that the transverse beams are more or less parallel to each other. The several holes at the upper end of the head piece are spaced transversely to the row of post so that the transverse beam can be attached at that hole which is closest to the longitudinal axis of the row of posts. Preferably, only one fastening element, for example a screw/bolt, is used to attach the transverse beam to the head piece. Consequently, the inclination of the transverse beam can be changed without releasing it completely from the head piece, for example by merely slightly unscrewing the screw/bolt.

In its lower part the head piece preferably is provided with several elongated holes which point in the longitudinal direction of the head piece. In the post or in its bridge, respectively, there are preferably provided corresponding round holes through which suitable fastening elements such as screws/bolts can be guided so as to attach the head piece at each one of the elongated holes on the post. The elongated holes allow for a certain variation in height when mounting the head piece. Thus, possible differences in height between the individual posts can be offset if, for example, it was not possible to position said posts in the ground at exactly the same depth. An elongated hole can have a length of 30-50 mm, for example.

Preferably, in the head piece, there are provided several elongated holes, in particular two, four or six elongated holes. Thus, it is possible to securely attach the head piece to the post, even if only a relatively small standard screw/bolt, such as an M12 screw/bolt, is guided through each individual elongated hole.

A particular advantage of the invention is that the configuration chosen for the head piece makes it possible to attach it both to the post and to the transverse beam using the same connecting elements, in particular bolt-nut-pairs of the same size, particularly preferably M12 bolts and corresponding nuts. Such material is inexpensive, and the use of only a single screw/bolt size simplifies and accelerates the assembly process.

Preferably, the transverse beam is also designed as a profiled element, in particular a Z, U or T profiled element. The head pieced is attached preferably to the bridge or middle part of the profile, which rests more or less vertically against the middle part of the head piece.

Preferably, the post, the head piece, the transverse beam and the strut are made as profiled elements. This allows for a particularly inexpensive manufacture of the device according to the invention.

According to a special embodiment, the head piece and the transverse beam are made with an identical profile, in particular a U profile.

These and other advantages of the invention will be further understood and appreciated by those skilled in the art by references to the following written specification, claims and appended drawings.

### BRIEF DESCRIPTION OF THE DRAWINGS

The invention will now be explained in more detail with reference to the appended figures. The figures show:

FIG. 1 is a perspective view of a device according to the invention;

FIG. 2 is a perspective view of a first embodiment of the post, the head piece, the transverse beam and the strut;

FIG. 3 is a cross-section top plan view through the post and the head piece along the line III-III in FIG. 2;

FIG. 4 is a perspective view of the post, the head piece, the transverse beam and the strut according to a second embodiment;

FIG. 5 is a cross-section top plan view of the second embodiment through the post and the head piece along the line V-V in FIG. 4;

FIG. 6 is a side elevational view of a head piece; and

FIG. 7 is a side elevational view of the device according to the invention in two different inclined positions of the transverse beam.

Identical parts in the figures are denoted by the same reference signs.

### DETAILED DESCRIPTION OF THE PREFERRED EMBODIMENTS

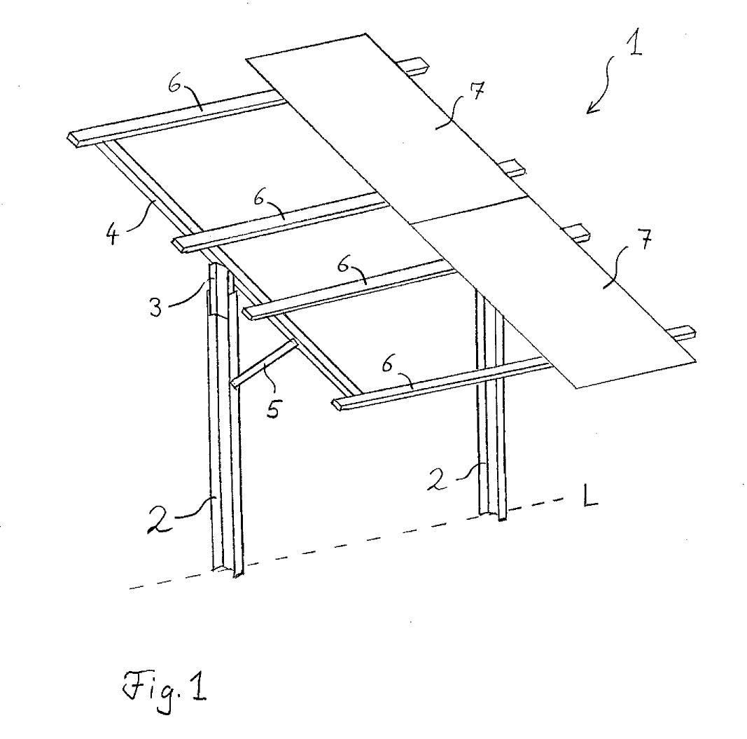

For purposes of description herein, the terms “upper,” “lower,” “right,” “left,” “rear,” “front,” “vertical,” “horizontal,” and derivatives thereof shall relate to the invention as oriented in FIG. 1. However, it is to be understood that the invention may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other characteristics relating to the embodiments disclosed herein are not to be considered as limiting, unless the claims expressly state otherwise.

FIG. 1 shows the basic structure of a support according to the invention. Preferably, said support is a fixed support, i.e. the azimuth angle is not followed. Also the inclination of the transverse beams 4 relative to the horizontal plane usually remains constant after the assembly process, however for each solar plant the inclination can be adjusted separately by changing the length of the struts 5, in particular it can be optimized for a maximum of solar irradiation depending on the latitude.

The support comprises a row of two or more posts 2, which are lined up at regular distances along a line L. The posts 2 are deeply rammed into the ground, for example, or otherwise anchored to the ground. At the upper end of each post 2 a head piece 3 is attached, and at said head piece, in turn, there is attached a transverse beam 4, which is inclined relative to the horizontal plane. The direction of inclination of the transverse beam 4 is fixed and the attachment is reinforced by the strut 5, which runs between each transverse beam 4 and the respective post 2. Several longitudinal beams 6, which are parallel to the line L, are put onto the transverse beams, and they are attached to the transverse beams 4 for example by means of screws/bolts. On the longitudinal beams 6, in turn, the solar modules 7 are placed and attached by means of suitable clamps or other fastening elements. FIG. 1 shows only two solar modules 7, whereas in a completed solar plant module 7 by module 7 are lined up and mounted on a row of supports comprising many posts 2 and transverse beams 4.

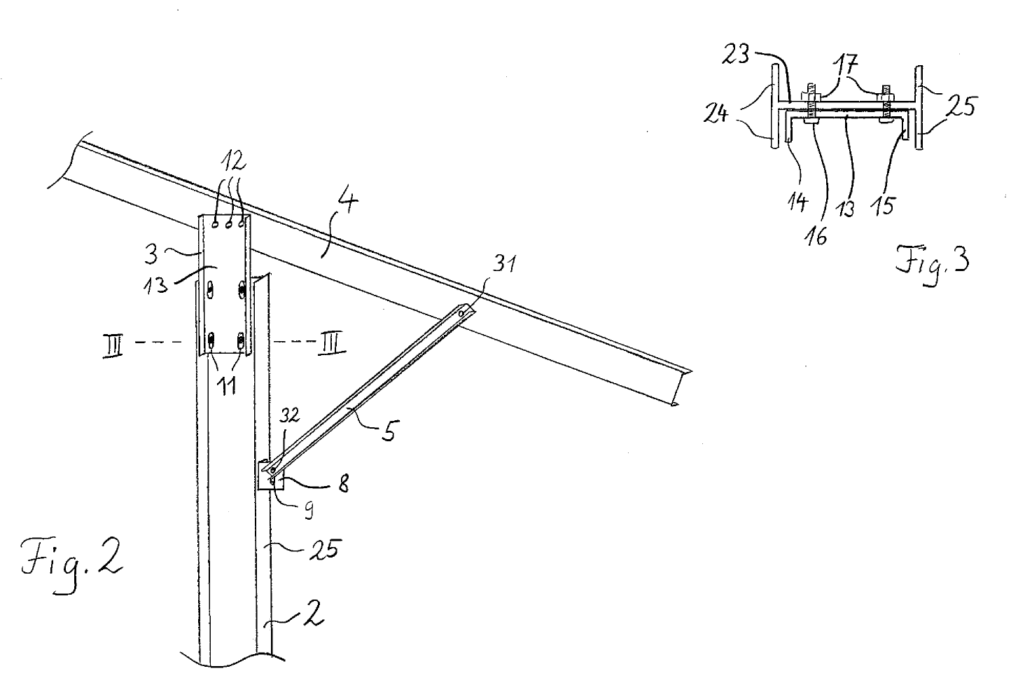

FIG. 2 shows in more detail the attachment of a transverse beam 4 at a post 2. In this case, the post 2 is a double T or I profiled element, in particular an IPE (European Standard) steel girder. As can be seen in the cross-section of FIG. 3, it has a flat bridge 23 and double flanges 24, 25 at the sides. The head piece 3, which in this embodiment is designed as a U profiled element, is positioned on one side of the bridge 23. The U profiled element has a middle part 13, which is also flat, and two leg sections 14, 15. In the middle part 13 of the head piece 3, there are arranged four elongated holes 11, which are arranged in two vertical and horizontal rows, respectively. Alternatively, it is also possible to provide more than two horizontal rows or more than two vertical rows of elongated holes 11.

Through each of the elongated holes 11 there is guided a screw/bolt 16, which protrudes through a corresponding round hole in the bridge 23 of the post and which is held on the reverse side by means of a nut 17.

The U profile of the head piece 3 is narrower than the double T profile of the post 2. In some embodiments, the width can also be such that the head piece 3 can be fitted basically positively between the flanges 24, 25 of the post 2 so that the leg sections 14, 15 rest directly against the flanges 24, 25 and, thus, the head piece 3 is held positively on the post 2 in the sideways direction.

In its upper region the middle part 13 of the head piece 3 comprises three holes 12 arranged horizontally next to each other. A screw/bolt of the same kind as the above-mentioned screws/bolts 16 is guided through one of said holes, by means of which screw/bolt the transverse beam 4 is attached to the head piece 3.

Approximately halfway between the attachment at the head piece and the lower end of the transverse beam 4 the strut 5 is attached to the transverse beam 4 by means of a screw/bolt 31. The strut 5 has the shape of a U profiled element at the end of whose middle part corresponding holes for the screws/bolts 31 and 32 are provided. The screw/bolt 32 is guided through an elongated hole 9 in an angled piece 8, which is attached to the flange 25 of the IPE beam of the post 2, for example by bolting or welding. Slight adjustments to the angle of inclination of the transverse beam 4 are possible by means of the elongated hole 9.

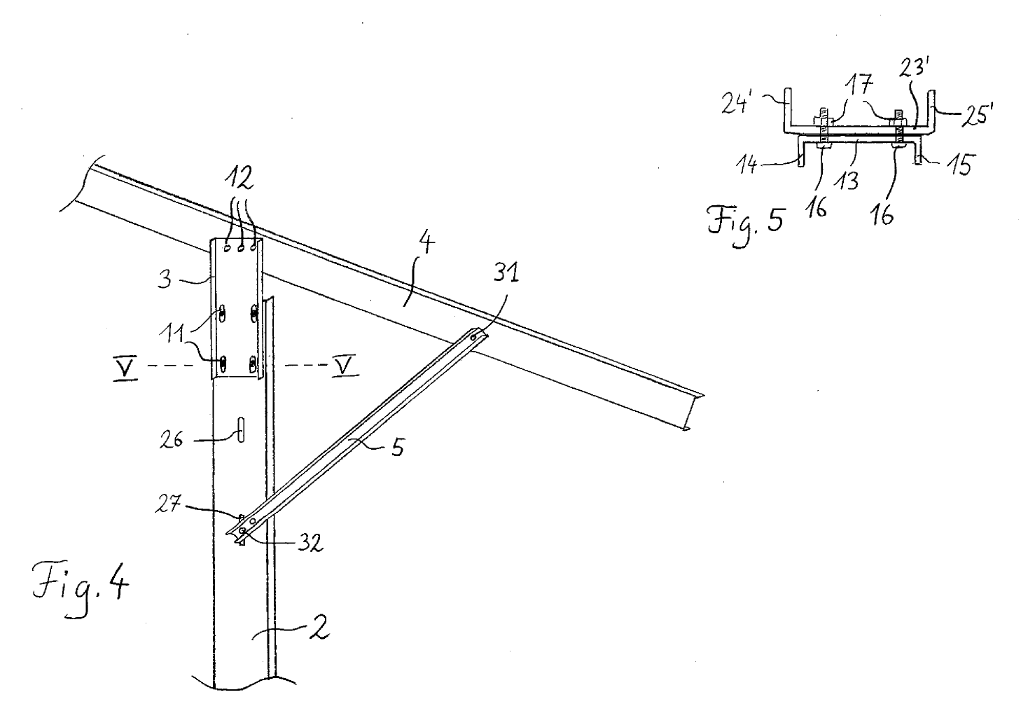

FIG. 4 shows a different embodiment, wherein the post 2 is designed as a U profiled element. Thus, in profile, the post 2, in turn, has a bridge 23′ and two flanges 24′and 25′ protruding to the same side, as can be seen in FIG. 5. The head piece 3, in turn, is a U profiled element with the leg sections 14, 15. The middle part 13 of the head piece 3 rests positively against the middle part or bridge 23 of the post 2. The head 3 is structurally identical to the embodiment of FIG. 2 and attached in the same manner to the post 2 at the elongated holes 11 and to the transverse beam 4 at the holes 12 by means of screws/bolts 16.

The main advantage of a post 2 having a U-shaped profile is that the elongated holes 26, 27, to which the strut 5 can be attached in different vertical positions, can be formed directly on the post 2, i.e. in its bridge 23′. Therefore, no angle piece 8 is required. The upper elongated hole 26 marks a position in which the transverse beam 4 is arranged at least essentially horizontally, if the lower end of the strut 5 is bolted at the elongated hole 26. In the position shown, a screw/bolt 32 is used to attach the strut 5 at the elongated hole 27, and the transverse beam and, thus, the entire support frame with the solar modules 7 is accordingly inclined towards the south. At each end of the strut 5 several holes can be provided, as is shown in FIG. 4, in order to adjust the angle of inclination of the transverse beam 4 by choosing one of the holes.

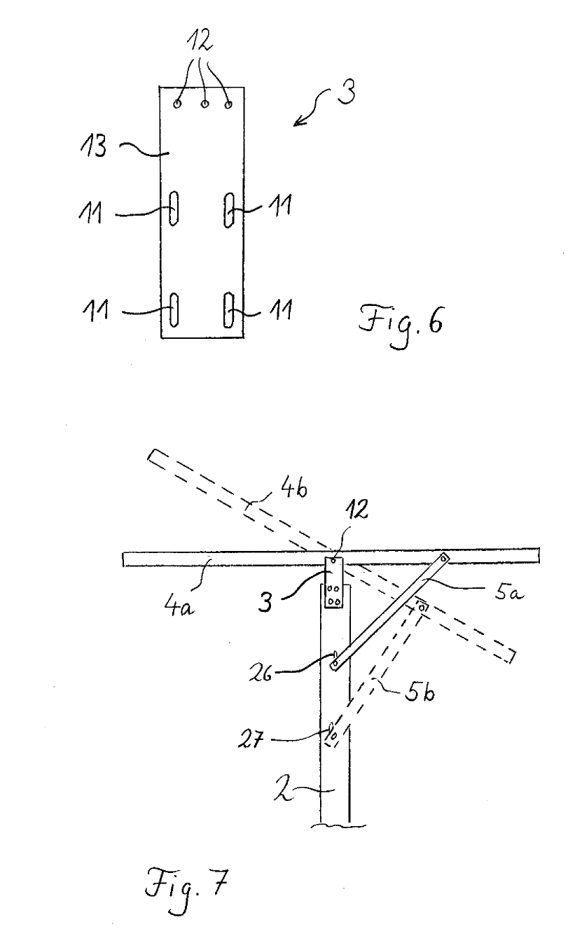

FIG. 6 is a side elevational view of the flat middle part 13 of a head piece 3. The leg sections 14, 15 of the U profile protrude from the paper plane and, consequently, cannot be seen. The figure shows in detail a row of several holes 12 in the upper region, wherein a screw/bolt is put through one of said holes for attachment on the transverse beam 4. Furthermore, four elongated holes 11 are visible, which are provided on the post 2 so as to accommodate screws/bolts 16.

FIG. 7 schematically shows a side view of a device according to the invention in two different inclination positions. In the position shown in continuous lines, the transverse beam 4 is basically horizontal since the strut 5a is bolted to the post 2 at the elongated hole 26. Preferably, this position is mounted first when assembling the solar plant since a horizontal position of the transverse beam 4a, and, thus, of the entire support frame, makes it possible to put the longitudinal beams 6 and/or the solar module 7 at first in the right location onto the transverse beams 4a and then to attach them there without hurry.

Once this part of the assembly process has been completed, the screw/bolt by means of which the transverse beam 4 is attached at the hole 12 of the head piece 3 is slightly unfastened. Then, the screw/bolt guided through the elongated hole 26 is unscrewed and the entire support frame tilted to the right until the lower end of the strut reaches the lower elongated hole 27. The strut is then bolted at the elongated hole 27 at this position 5b, and the screw/bolt, by means of which the transverse beam 4b is attached to the head piece 3, is tightened. After this much facilitated and easy assembly process, in which preferably only one type of bolt-nut-pairs is used, the transverse beam 4b is in the operating position.

In the foregoing description, it will be readily appreciated by those skilled in the art that modifications may be made to the invention without departing from the concepts disclosed herein. Such modifications are to be considered as included in the following claims, unless these claims by their language expressly state otherwise.

1-15. (canceled)

16. A device for supporting solar modules, comprising:
a first post and a second post each having an upper region, the first post and the second post arranged in a row;
a first head piece attached to the upper region of the first post and a second head piece attached to the upper region of the second post, wherein the first head piece and the second head piece each have a profile;
a first transverse beam fixed to the first head piece and a second transverse beam attached to the second head piece, wherein the first and second beams are oriented substantially transversely to the tow of beams; and
a first strut extending between the first post and the first transverse beam, and a second strut extending between the second post and the second transverse beam.

17. The device of claim 16, wherein the profile of the first head piece has a longitudinal direction that extends substantially parallel with a longitudinal direction of the first post, and wherein the profile of the second head piece has a longitudinal direction that extends substantially parallel with a longitudinal direction of the second post.

18. The device of claim 16, wherein the first strut is adapted to couple to the first post in at least two vertically spaced locations, including a first location, wherein the first transverse beam is at a first angle of inclination with respect to a horizontal plane, thereby maximizing solar irradiation, and a second location, wherein the first transverse beam is at a second angle of inclination that is less that the first angle of inclination.

19. The device of claim 17, wherein the second location orients the first transverse beam substantially within the horizontal plane.

20. The device of claim 16, wherein the first and second locations each include an elongated hole extending through the first post and adapted to receive a fastening element therethrough that attaches the first strut to the first post.

21. The device of claim 16, further including a first angle piece attached to the first post at the first location and a second angle piece attached to the first post at the second location, wherein the first and second angle pieces each include an elongated hole extending therethrough and adapted to receive a fastening element therethrough that attached the first strut to the first post.

22. The device of claim 16, wherein the first and second struts are each provide with at least one of a U-shaped profile and an L-shaped profile, the first and second struts each include a first end and a second end, and wherein the first and second end of each both the first strut and the second strut includes a hole at which the first strut is attached the first post and the second strut is attached to the second post.

23. The device of claim 16, wherein each of the posts comprises at least one of a U-shaped profile and an L-shaped profile.

24. The device of claim 16, wherein the profile of each of the first head piece and the second head piece comprises at least one of a U-shape and an L-shape.

25. The device of claim 16, wherein the profile of the first head piece comprises a U-shape having a two leg sections and a flat middle part connecting the leg sections, and wherein the middle part rests against the first post and the first transverse beam and is connected to the first post and the first transverse beam by connecting elements extending through holes arrange in the middle part.

26. The device of claim 16, wherein the profile of the first head piece comprises at least one of a U-shape having two leg sections and a flat middle part and an L-shape having a leg section and a flat middle part, the first post includes a profile having at least one flange and a bridge, and wherein the middle part of the first head piece rests positively against the bridge of the first post.

27. The device of claim 16, wherein the first head piece includes an upper region that includes at least two horizontally spaced holes, and wherein the first transverse beam is attached to the first head piece at least one of the two horizontally spaced holes.

28. The device of claim 27, wherein the first transverse beam is bolted to the first head piece through at least one of the two horizontally spaced holes of the first head piece.

29. The device of claim 16, wherein the first head piece is attached to the first post by several fastening elements, which are guided through several elongated holes located with the first head piece.

30. The device of claim 29, wherein the several fastening elements include at least one of bolts and screws.

31. The device of claim 16, wherein the first post is attached to the fist head piece and the first head piece is fixed to the first transverse beam by mechanical fasteners having substantially similar dimensions.

32. The device of claim 16, wherein the first transverse beam and the second transverse beam each have at least one of a Z-shaped profile, a U-shaped profile and a T-shaped profile.

33. The device of claim 16, further including:
A plurality of longitudinal beams extending substantially parallel to the row of posts and fixed to the first and second transverse beams.

34. The device of claim 16, wherein the first and second posts, the first and second head pieces, and the first and second transverse beams are each profiled elements.
